(19) United States
(12) Patent Application Publication
(10) Pub. No.: US 2016/0071777 A1
(43) Pub. Date: Mar. 10, 2016

(54) SEMICONDUCTOR PACKAGE AND SEMICONDUCTOR DEVICE

(71) Applicant: Panasonic Intellectual Property Management Co., Ltd., Osaka-shi, Osaka (JP)

(72) Inventors: Kazuhiro YAHATA, Osaka (JP); Takashi UNO, Hyogo (JP); Hikaru IKEDA, Osaka (JP)

(21) Appl. No.: 14/404,393

(22) PCT Filed: Mar. 13, 2014
(86) PCT No.: PCT/JP2014/001450

§ 371 Date: Nov. 26, 2014

(30) Foreign Application Priority Data
Mar. 28, 2013 (JP) 2013-069211

(51) Int. Cl. H01L 23/047; H01L 23/373; H01L 23/00; H01L 23/10

(52) U.S. Cl. CPC H01L 23/047; H01L 23/10; H01L 23/373; H01L 24/83; H01L 2924/095

(57) ABSTRACT

A semiconductor package or a semiconductor device includes a heat sink onto which a semiconductor or a matching circuit is to be placed, a lead terminal which is to be electrically-connected to the semiconductor or the matching circuit on the heat sink, and a securing member which secures the lead terminal to the heat sink, wherein the securing member is formed by a composite resin material in which a resin and a ceramic powder are mixed.

### TECHNICAL FIELD

This disclosure relates to a semiconductor package which houses a semiconductor, and a semiconductor device which includes the semiconductor package housing the semiconductor.

### BACKGROUND ART

A semiconductor package which houses and is equipped with a semiconductor may be a hollow resin package, where the semiconductor is sealed by a resin, for example (shown in Patent Document 1). In Patent Document 1, a reinforcing member for preventing deformation of a package body is buried, separately from a lead frame, in a peripheral wall made by resin mold to form a cavity for housing a semiconductor element.

### Patent Document

Patent Document 1: JP 2004-193294 A

### SUMMARY OF INVENTION

### Technical Problem

In recent years, however, it is required to make various efforts in a semiconductor package and a semiconductor device including the semiconductor package, for example, to increase their heat resistance during manufacture or to reduce their manufacturing costs.

Accordingly, an object of one aspect of the disclosure is to solve the above problems and to provide a semiconductor package and a semiconductor device including the semiconductor package where theft heat resistance during manufacture is increased and their manufacturing costs are reduced.

### Solution to Problem

In order to achieve the above object, one aspect of the disclosure is configured as follows.

A semiconductor package includes a heat sink which is a conductive plate and onto which a semiconductor or a matching circuit is to be placed, a lead terminal which is to be electrically-connected to the semiconductor or the matching circuit on the heat sink, and a securing member which secures the lead terminal to the heat sink, wherein the securing member is formed by a composite resin material in which a resin and a ceramic powder are mixed.

A semiconductor device includes a semiconductor or a matching circuit, a heat sink which is a conductive plate and onto which the semiconductor or the matching circuit is bonded, a lead terminal electrically-connected to the semiconductor or the matching circuit on the heat sink, and a securing member which secures the lead terminal to the heat sink, wherein the securing member is formed by a composite resin material in which a resin and a ceramic powder are mixed.

### Effects of Invention

According to the aspects of the disclosure, the semiconductor package and the semiconductor device including the semiconductor package can increase their heat resistance during manufacture and reduce their manufacturing costs.

### BRIEF DESCRIPTION OF THE DRAWINGS

Features and aspects thereof of the disclosure will become apparent from the following description taken in conjunction with the preferred embodiments for the appended drawings.

FIG. 1A is a top view of a semiconductor package 100 according to an embodiment of one aspect of the disclosure.

FIG. 1B is an A-A cross-sectional view of FIG. 1A.

FIG. 1C is a B-B cross-sectional view of FIG. 1A.

FIG. 2A is a top view of a semiconductor device 110 according to the embodiment.

FIG. 2B is a C-C cross-sectional view of FIG. 2A.

FIG. 2C is a D-D cross-sectional view of FIG. 2A.

FIG. 3A is a view for explaining a manufacturing method of the semiconductor package 100 according to the embodiment.

FIG. 3B is a view for explaining the manufacturing method of the semiconductor package 100 according to the embodiment.

FIG. 3C is a view for explaining the manufacturing method of the semiconductor package 100 according to the embodiment.

FIG. 3D is a view for explaining the manufacturing method of the semiconductor package 100 according to the embodiment.

FIG. 3E is a view for explaining the manufacturing method of the semiconductor package 100 according to the embodiment.

FIG. 4A is a view for explaining a manufacturing method of the semiconductor device 110 according to the embodiment.

FIG. 4B is a view for explaining the manufacturing method of the semiconductor device 110 according to the embodiment.

FIG. 4C is a view for explaining the manufacturing method of the semiconductor device 110 according to the embodiment.

FIG. 5A is a top view of a semiconductor package 200 according to variation 1 of the embodiment.

FIG. 5B is an E-E cross-sectional view of FIG. 5A.

FIG. 5C is a F-F cross-sectional view of FIG. 5A.

FIG. 6A is a top view of a semiconductor package 300 according to variation 2 of the embodiment.

FIG. 6B is a G-G cross-sectional view of FIG. 6A.

FIG. 6C is a H-H cross-sectional view of FIG. 6A.

FIG. 7A is a top view of a semiconductor package 400 according to variation 3 of the embodiment.

FIG. 7B is an I-I cross-sectional view of FIG. 7A.

FIG. 7C is a J-J cross-sectional view of FIG. 7A.

### DESCRIPTION OF EMBODIMENTS

The inventors found following contents.

In a recent mobile-phone base station or the like, a high-frequency power amplifier is used. A semiconductor device used in such a high-frequency power amplifier includes a semiconductor package housing a semiconductor and often incorporates a matching circuit in the semiconductor package in order to input/output signals to/from the semiconductor efficiently. This leads to a trend of an increasing size of a die-pad (a size of the semiconductor package), onto which the semiconductor, the matching circuit, or the like is mounted.

In addition, when used, the high-frequency power amplifier generates heat from the semiconductor device, and the generated heat is directly dissipated from a housing, a heat sink or the like. In order to ensure this heat dissipation, the semiconductor of the semiconductor device is often mounted on a die pad of good thermal-conductivity via a die-bonding material of good thermal-conductivity and a high melting-point. In many cases, a back surface of the die pad is not covered with resin.

The above-described features are essential for the semiconductor package used in the high frequency power amplifier.

Currently, there are various semiconductor packages, which can be categorized broadly into a resin-sealed package and a ceramic hollow package.

The resin-sealed package houses a semiconductor, a component, and a wire connecting them, and has been subjected to resin molding to protect them. The resin-sealed package can be manufactured in bulk at low costs, thereby most-commonly used as a consumer semiconductor package.

However, if the semiconductor device including the resin-sealed package is used for a long period of time, rise and fall of temperature will be repeated in the semiconductor device and its surrounding environment. The repetition of the temperature change and the fact that a thermal expansion coefficient is different between the molding resin and components, such as the semiconductor, the matching circuit, or a lead frame, may trigger detachment in an interface between the components and the molding resin, thereby cutting off the wire for connecting the semiconductor and thus resulting in failure. In particular, the high-frequency power amplifier generates large amount of heat and is provided with a package of large size, thereby leading to make the detachment in the molding resin notably.

A ceramic hollow package is a package where a semiconductor is sealed in a hollow package using ceramic. The ceramic hollow package uses the ceramic instead of resin, thereby enabling a die bonding under a high temperature and achieving excellent reliability. The ceramic hollow package, however, has a problem of taking many steps when processing the ceramic or performing silver brazing of the ceramic. Also, the silver brazing of the ceramic generates stresses due to a difference in thermal expansion coefficients between the ceramic and a heat sink. In order to release the stresses, the heat sink needs to be formed by a laminated structure of molybdenum or tungsten, or by an alloy thereof. This leads to a problem of increasing costs highly.

For these problems, a hollow package using resin has been taken into consideration, but in the case of using only the resin, the resin itself cannot withstand a high temperature during a die bonding and cannot retain its shape. It can also be taken into consideration to form a resin structure after a die bonding, but it makes processes highly-complicated, thereby leading to increased costs.

As a result of intensive study based on the above findings, the inventors invented a semiconductor package and a semiconductor device described below.

### Embodiment

Hereinafter, a semiconductor package 100 according to an embodiment of one aspect of the disclosure will be described with reference to the drawings.

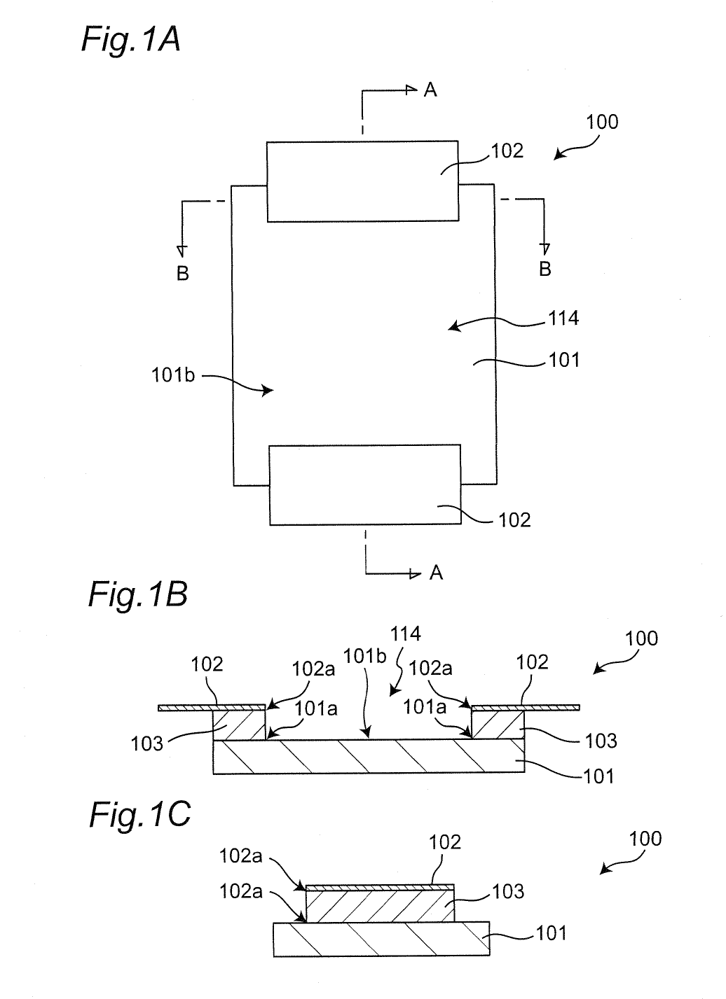

FIGS. 1A-1C illustrate the semiconductor package 100 according to the embodiment, respectively. FIG. 1A is a top view of the semiconductor package 100. FIG. 1B is an A-A cross-sectional view of FIG. 1A. FIG. 1C is a B-B cross-sectional view of FIG. 1A. The “semiconductor package” refers to a package which is to house a semiconductor and in this specification refers to a semiconductor package where a semiconductor has not been mounted or bonded yet. As shown in FIGS. 1A-1C, the semiconductor package 100 includes a heat sink 101, two lead terminals 102, and securing members 103 which secure the lead terminals 102 to the heat sink 101.

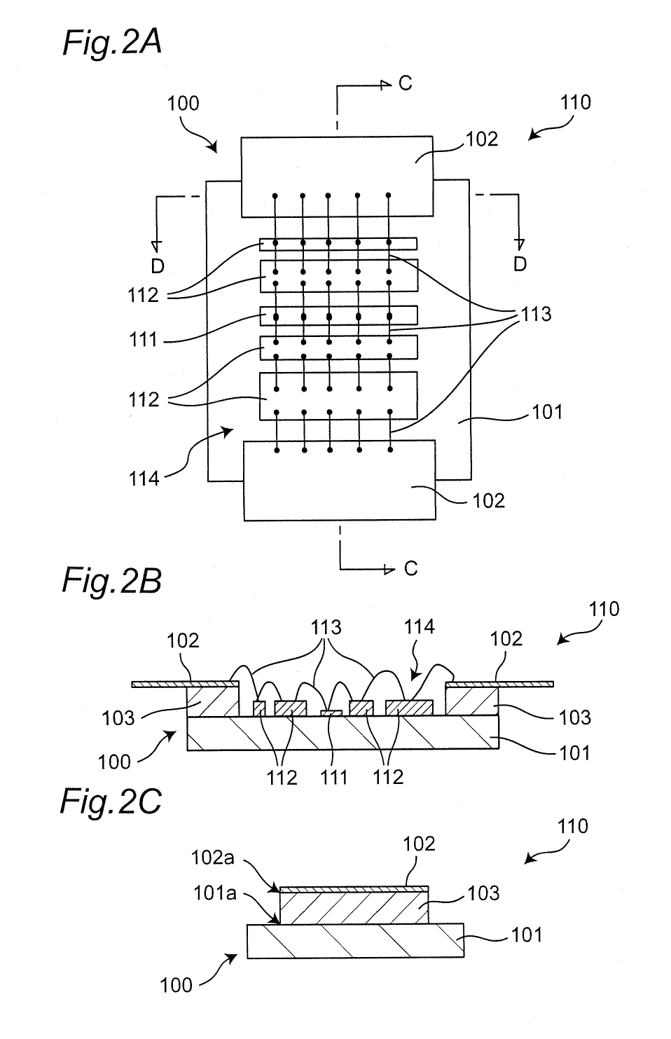

The heat sink 101 is a base for mounting a semiconductor or a matching circuit (not shown in FIGS. 1A-1C but shown in FIGS. 2A-2C) thereon, and has a role to dissipate heat generated from the semiconductor or the matching circuit. The heat sink 101 is a conductive, flat plate.

The lead terminals 102 are connection terminals to the outside. FIGS. 1A and 1B show the two lead terminals 102 for input and output, respectively.

Both the heat sink 101 and the lead terminals 102 in the embodiment are formed by (include) a material (for example, copper) having low electrical resistance and high thermal conductivity.

As shown in FIG. 1B, the securing members 103 which secure the lead terminals 102 to the heat sink 101 are arranged between the heat sink 101 and the lead terminals 102. The securing members 103 are formed by (include) a composite resin material in which a resin and a ceramic powder are mixed (where kneading, heating and curing are included).

In the embodiment, the ceramic powder of the composite resin material forming the securing member 103 is an inorganic filler of high thermal conductivity, such as alumina or silica, and the resin of the composite resin material is an epoxy resin. Also, the ceramic powder in the embodiment is high-dielectric whose relative dielectric constant is 10 or more. A mixing ratio of the ceramic powder in the composite resin material is 70% to 95% by weight, for example.

The heat sink 101 and the securing members 103 define a cavity 114 for housing the semiconductor or the matching circuit. The cavity 114 is a space fenced by the heat sink 101 and the securing member 103, etc.

In the semiconductor package 100 having the above-described configuration, roughened parts are formed on surfaces 1018 and 102a among surfaces of the lead terminals 102 and the heat sink 101, the surfaces 101a and 102a being in contact with the securing members 103. Also, the roughened parts have been oxidized to form oxidized parts.

In addition, the surfaces of the heat sink 101, the lead terminals 102 and the securing member 103 are plated except for their contacting portions where they are in contact with each other. For example, the upper surface 101b of the heat sink 101 is plated other than the contact surface 101a in contact with the securing members 103.

Next, a semiconductor device 110, which can be made by mounting and bonding the semiconductor or the matching circuit onto the semiconductor package 100 described with reference to FIGS. 1A-1C, will be explained with reference to FIGS. 2A-2C, FIG. 2A is a top view of the semiconductor device 110. FIG. 2B is a C-C cross-sectional view of FIG. 2A. FIG. 2C is a D-D cross-sectional view of FIG. 2A. The “semiconductor device” refers to a semiconductor device where the semiconductor or the matching circuit has been mounted and bonded onto the semiconductor package. As shown in FIGS. 2A-2C, the semiconductor device 110 includes the semiconductor package 100 including the heat sink 101, the lead terminals 102, and the securing members 103, a semiconductor 111, matching circuits 112, and wires 113.

The semiconductor 111 is a semiconductor element mounted on the semiconductor package 100, with being housed in the cavity 114. Input and output of signal are performed in the semiconductor 111.

The matching circuits 112 are circuits for converting/matching impedance in the semiconductor 111. The matching circuits 112 with the semiconductor 111 are mounted on the semiconductor package 100 and housed in the cavity 114. Matching circuits are required in a high-frequency/high-power application, in particular.

As shown in FIGS. 2A and 2B, both the semiconductor 111 and the matching circuits 112 are mounted on the upper surface 101b of the heat sink 101, with being placed between the lead terminals 102 and between the securing members 103. FIGS. 2A and 2B show the one semiconductor 111 and the four matching circuits 112, respectively, but numbers of them are not limited thereto. Only the semiconductor 111 (not including the matching circuits 112) may be provided.

As shown in FIGS. 2A and 23, the wires 113 are connecting the semiconductor 111 and the matching circuits 112, connecting the matching circuits 112 with each other, and connecting the matching circuits 112 and the lead terminals 102. The connections of the semiconductor 111, the matching circuits 112 and the lead terminals 102 by the wires 113 are to connect the semiconductor 111 to the lead terminals 102 used for connection to the outside, thereby enabling input/output of signal from/to the outside.

The semiconductor device 110 further includes a U-shaped lid (cover) for sealing, not shown in drawings. Disposing the lid over the heat sink 101 and the lead terminals 102 seals the semiconductor 111 and the matching circuits 112 in the hollow semiconductor device 110 (in the cavity 114).

The securing members 103 have thicknesses larger than thicknesses of the semiconductor 111 and the matching circuits 112, and define the cavity 114 with the heat sink 101.

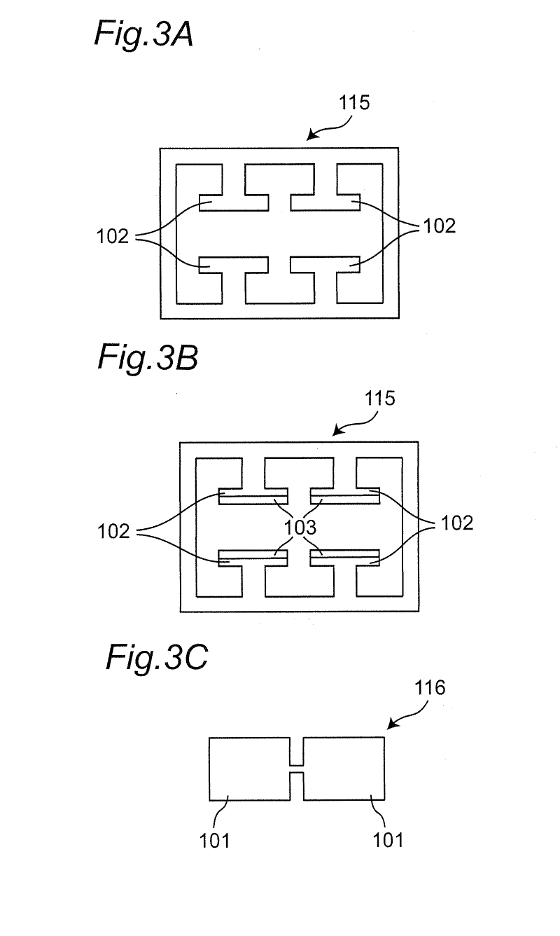

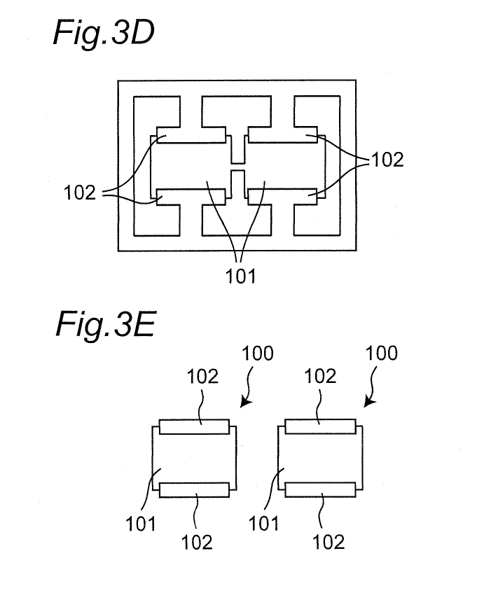

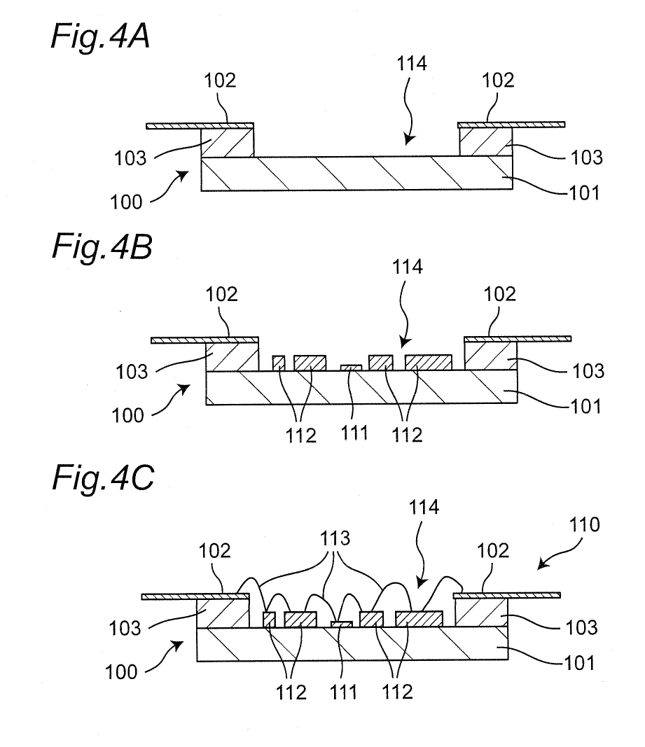

Next, a manufacturing method of each of the semiconductor package 100 and the semiconductor device 110 described above will be described with reference to FIGS. 3A-3E and FIGS. 4A-4C, respectively. FIGS. 3A-3E show the manufacturing method of the semiconductor package 100, and FIGS. 4A-4C show the manufacturing method of the semiconductor device 110.

First, as shown in FIG. 3A, a lead body 115 which connects four lead terminals 102 is prepared for manufacturing the semiconductor package 100. More specifically, the lead body 115 has been made by a raw material of the lead terminals 102 using a separate mold in advance with inserting (fitting) the raw material into a channel of the mold having a shape of the lead body 115.

In addition to making the lead body 115, roughened parts are formed by roughening parts (corresponding to the contact surfaces 102a) of surfaces of the lead terminals 102 of the lead body 115 in this embodiment.

Next, a securing member 103 is attached to each of the four lead terminals 102 of the lead body 115. More specifically, another mold is attached onto the mold housing the lead body 115, and then filled with a raw material of the securing members 103 (a kneading resin as a composite resin material where an epoxy resin and a filler have been mixed with each other in this embodiment). In this way, as shown in FIG. 3B, the securing members 103 are attached onto the lead terminals 102 of the lead body 115. At this time, the securing members 103 are disposed on the roughened parts (i.e, the contact surfaces 102a) of the lead terminals 102.

While attaching the securing members 103 onto the lead terminals 102 as shown in FIG. 3B, a heat sink body 116 which connects two heat sinks 101 is prepared as shown in FIG. 3C. More specifically, the heat sink body 116 has been made from a raw material of the heat sinks 101 using a separate mold in advance with inserting (fitting) the raw material into a channel of the mold having a shape of the heat sink body 116. In the heat sink body 116, roughened parts are formed by roughening parts (corresponding to the contact surfaces 101a) of surfaces of the heat sinks 101 as is the case with the lead terminals 102.

Next, the heat sink body 116, and the resin and the lead body 115 are overlapped and then bonded together. More specifically, the two molds are coupled together by face-down such that the heat sink body 116 shown in FIG. 3C overlaps on the resin (the securing members 103) and the lead body 115 as shown in FIG. 3B. At this time, the securing members 103 are disposed to contact with the contact surfaces 101a of the heat sinks 101.

In this state, heating is conducted to raise an ambient temperature such that the ambient temperature becomes a curing temperature of the resin of the composite resin material of the securing members 103. At this time, oxidizing due to the heating makes oxidized parts (oxidized film) on the entire surfaces of the heat sinks 101 and the lead terminals 102. Then, cooling is conducted and thus the securing members 103 are cured. Thus, the heat sinks 101 and the lead terminals 102 are brought into close contact with the securing members 103.

Then, plating is applied to the surfaces of the heat sinks 101 and the lead terminals 102 shown in FIG. 3D. More specifically, alkali process is applied to the surfaces of the heat sinks 101 and the lead terminals 102 other than the contact surfaces 101a, 101b to the securing members 103 so as to remove the oxidized parts, and then the plating is applied to the surfaces where the oxidized parts are removed.

Thus, the oxidized parts are not removed from the contact surfaces 101a,102a contacting with the securing members 103 while removed from the surfaces not contacting with the securing members 103 (where the plating is also applied) among the surfaces of the heat sinks 101 and the lead terminals 102.

Forming the plated portion after forming the oxidized parts in this way can conduct a plating process while enhancing adhesion by the oxidized parts. The adhesion can be enhanced by oxidizing the surfaces in such a way, but oxidizing the surfaces where the roughened parts are formed can further enhance the adhesion.

Eventually, as shown in FIG. 3E, dividing the packages can manufacture the semiconductor package 100 including the heat sink 101, the lead terminals 102, and the securing members 103. In this embodiment, the two semiconductor packages 100 are manufactured at the same time, but not limited thereto, the above-described method or the like may manufacture one or more than two semiconductor packages 100 at the same time.

Next, a manufacturing method of the semiconductor device 110, which can be made by mounting/bonding the semiconductor, the matching circuits or the like onto the semiconductor package 100 as shown in FIGS. 3A-3E, will be described with reference to FIGS. 4A-4C.

First, as shown in FIG. 4A, the semiconductor package 100 shown in FIG. 3E is prepared. Next, as shown in FIG. 4B, the semiconductor 111 and the matching circuits 112 are mounted on the upper surface 101b of the heat sink 101 of the semiconductor package 100. More specifically, AuSn pellets are disposed on component-mounting positions of the upper surface 101b of the heat sink 101 in the cavity 114, and then the semiconductor 111 and the matching circuits 112 are disposed on the AuSn pellets. In this state, the semiconductor package 100 is disposed for a few minutes in a furnace where a temperature has been set above a melting temperature of AuSn (about 283° C. or higher). Thus, melting AuSn can mount the semiconductor 111 and the matching circuits 112 within the cavity 114 at the same time (i.e. die bonding).

Here, if a material such as AuSn having good thermal conductivity and a high melting point is used as a die bonding material, a heating temperature during the die bonding will reach at 300° C. or higher as an ambient temperature, for example.

On the other hand, an epoxy resin generally used as the resin of the composite resin material of the securing member 103 is thermosetting and has a curing temperature of 200° C. or lower and a glass transition temperature of 250° C. or lower. Thus, the glass transition temperature of the epoxy resin is exceeded by the heating temperature of 300° C. or more during the die bonding, and therefore the securing members 103 may not be able to hold its shape under such a high heating temperature. In this embodiment, however, the securing members 103 are formed by the composite resin material where the resin and the ceramic powder are mixed with each other. This can prevent possible detachment in an interface between the securing members 103 and the heat sink 101 or the lead terminals 102 and retain the shapes of the securing members 103 even if the heating temperature exceeds the glass transition temperature of the resin. In this specification, retaining of the shapes of the securing members 103 refers to that a volume reduction rate of the securing member(s) 103 after the heat bonding is 5% or less.

Next, a plurality of wires 113 are used to connect the semiconductor 111, the matching circuits 112, and the lead terminals 102. More specifically, wire bonding by the wires 113 connects the semiconductor 111 and the matching circuits 112, and connects the matching circuits 112 with each other, and connects the matching circuits 112 and the lead terminals 102, as shown in FIG. 4C. This leads to connect the semiconductor 111 and the lead terminals 102 electrically.

Then, covering the semiconductor device 110 with the lid can manufacture a hollow semiconductor device 110 where the semiconductor 111 and the matching circuits 112 are sealed within the semiconductor package 100.

Adopting the materials and the configurations as described above can use a low-cost material, and can use a die bonding material having a high melting point without taking high-cost steps. Further, it is possible to provide the semiconductor package 100 and the semiconductor device 110, where heat of the semiconductor 111 can be dissipated efficiently.

Also, in the semiconductor device 110 manufactured in such a way, the lead terminals 102 are electrically-connected to the heat sink 101 via the securing members 103 including the ceramic powder of high-dielectric. As a result, the impedance of the semiconductor device 110 changes in the securing member 103.

In general, the lead terminals 102 are to perform input/output of signal to/from inside the semiconductor package 100, and therefore desired not to affect the impedance inside the semiconductor package 100 and not to cause any loss. Therefore, a component which is disposed under the lead terminals 102 (i.e, the kneading resin constituting the securing member 103) is desired to have a small relative dielectric constant (for example, 10 or less) and a small dielectric tangent. However, this embodiment assumes that the dielectric constant of the securing members 103, which are members disposed under the lead terminal 102, is increased for actively using the lead terminal 102 as a matching circuit. Therefore, increasing the relative dielectric constant according to this embodiment makes a wavelength shortening, thereby causing a large change in the impedance.

As described above, the semiconductor package 100 according to this embodiment includes the heat sink 101 which is a conductive plate and onto which the semiconductor 111 or the matching circuit 112 is to be placed, the lead terminal 102 which is to be electrically-connected to the semiconductor 111 or the matching circuit 112 on the heat sink 101, and the securing member 103 which secures the lead terminal 102 to the heat sink 101, wherein the securing member 103 is formed by the composite resin material in which the resin and the ceramic powder are mixed. Also, the semiconductor device 110 according to this embodiment includes the semiconductor 111 or the matching circuit 112, the heat sink 101 which is a conductive plate and onto which the semiconductor 111 or the matching circuit 112 is bonded, the lead terminal 102 electrically-connected to the semiconductor 111 or the matching circuit 112 on the heat sink 101, and the securing member 103 which secures the lead terminal 102 to the heat sink 101, wherein the securing member 103 is formed by the composite resin material in which the resin and the ceramic powder are mixed.

The semiconductor package 100 and the semiconductor device 110 use the composite resin material, where the resin and the ceramic powder are mixed, as a material of the securing member 103, thereby increasing heat resistance during manufacture as compared with a case of forming the securing member 103 only by resin. Furthermore, the semiconductor package 100 and the semiconductor device 110 do not need a step such as silver brazing which is required if the securing member 103 is formed only by ceramic powder, thereby reducing their manufacturing costs. That is, increased heat resistance during manufacture and reduced manufacturing costs can be both realized.

According to the semiconductor package 100 and the semiconductor device 110 of this embodiment, the glass transition temperature of the resin mixed in the composite resin material of the securing member 103 is lower than the heating temperature under which the semiconductor 111 and the matching circuit 112 are mounted and bonded onto the heat sink 101. On the other hand, even if the semiconductor 111 is mounted and bonded on the heat sink 101 with being heated to a temperature above the glass transition temperature of the resin, mixing of the resin and the ceramic powder can retain the shape of the securing member 103. This can further increase the heat resistance during manufacture.

Also, according to the semiconductor package 100 and the semiconductor device 110 of the embodiment, the heat sink 101 or the lead terminal 102 has a roughened part in a position to have contact with the securing member 103. This can enhance adhesion between the heat sink 101 or the lead terminal 102 and the securing member 103, thereby improving reliability of the semiconductor package 100 and the semiconductor device 110.

Also, according to the semiconductor package 100 and the semiconductor device 110 of the embodiment, the heat sink 101 or the lead terminal 102 has an oxidized part in a position to have contact with the securing member 103. This can enhance the adhesion between the heat sink 101 or the lead terminal 102 and the securing member 103, thereby improving the reliability of the semiconductor package 100 and the semiconductor device 110.

Also, according to the semiconductor package 100 and the semiconductor device 110 of the embodiment, the heat sink 101 or the lead terminal 102 has a plated portion in a position not to have contact with the securing member 103. Thus, forming the plated portion in the position different from the oxidized part can perform a plating process while enhancing the adhesion by the oxidized part.

Also, according to the semiconductor package 100 and the semiconductor device 110 of the embodiment, the lead terminal 102 is electrically-connected to the heat sink 101 via the securing member 103, and the ceramic powder mixed in the composite resin material forming the securing member 103 is high-dielectric. Thus, the impedance of the semiconductor package 100 and the semiconductor device 110 is changed in the securing member 103, thereby furnishing the securing member 103 with a function as a matching circuit.

Also, the semiconductor package 100 and the semiconductor device 110 of the embodiment further include the matching circuit 112 on the heat sink 101 in addition to the semiconductor element 111. Thus, the semiconductor package 100 and the semiconductor device 110 can be effectively applicable to a high-power/high-frequency application, in particular.

The method according to the embodiment for manufacturing the semiconductor device 110 in which the semiconductor package 100 houses the semiconductor 111 or the matching circuit 112 includes making the semiconductor device 110 by securing the lead terminal 102 to the heat sink 101 with use of the securing member 103 formed by the composite resin material in which the resin and the ceramic powder are mixed, bonding the semiconductor 111 or the matching circuit 112 onto the heat sink 101 of the semiconductor device 110 by heating, and electrically-connecting the semiconductor 111 or the matching circuit 112 on the heat sink 101 to the lead terminal 102, wherein the shape of the securing member 103 is retained at the heating temperature under which the semiconductor 111 or the matching circuit 112 is bonded onto the heat sink 101.

Thus, the composite resin material in which the resin and the ceramic powder are mixed is used as the material of the securing member 103, thereby increasing the heat resistance during manufacture as compared with the case of forming the securing member 103 only by the resin. Furthermore, a step such as silver brazing which is required if the securing member 103 is formed only by ceramic powder is not needed, thereby reducing the manufacturing costs. That is, the increase of the heat resistance during manufacture and the reduction of the manufacturing costs can be both achieved.

The disclosure is not limited to the above embodiment, but may be implemented in other various aspects. For example, an opening or a concavo-convex shape may be formed in a part of the lead terminal 102 having contact with the securing member 103. This can enhance the adhesion between the lead terminal 102 and the securing member 103.

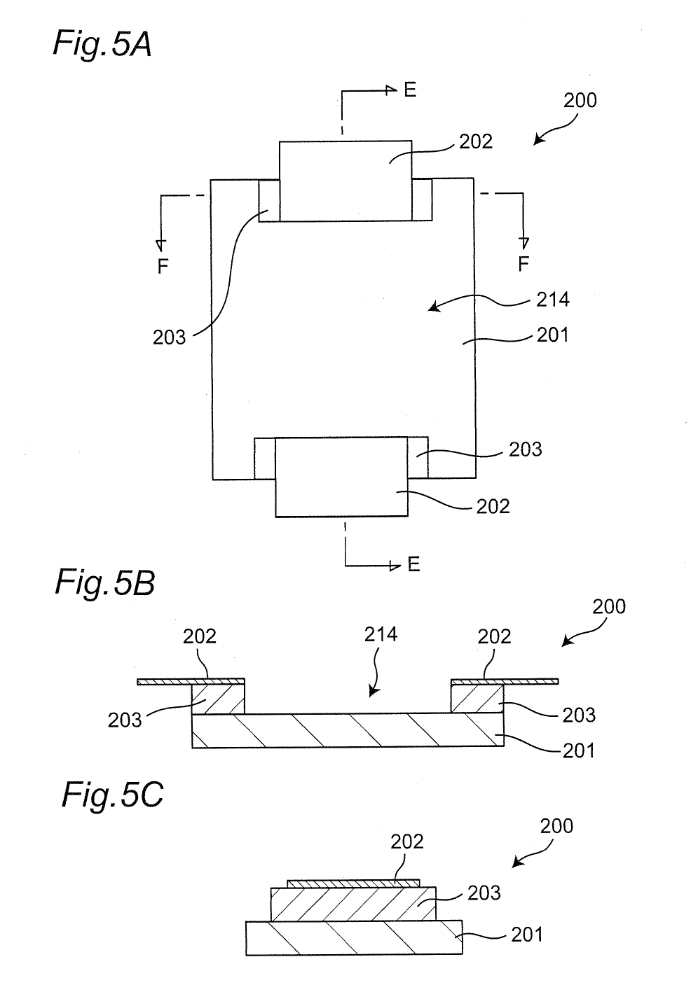

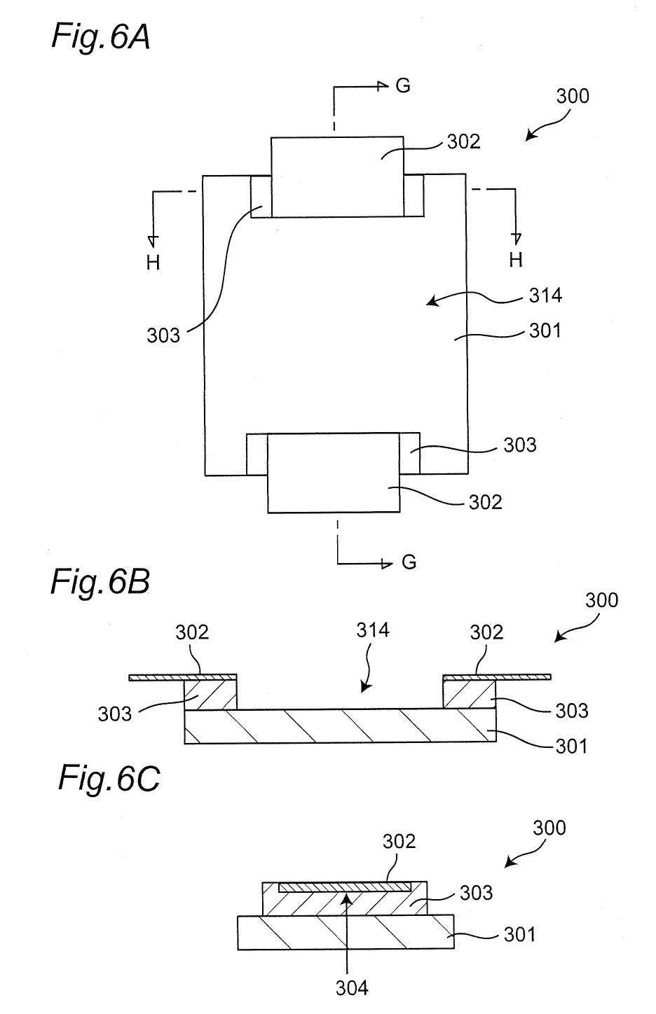

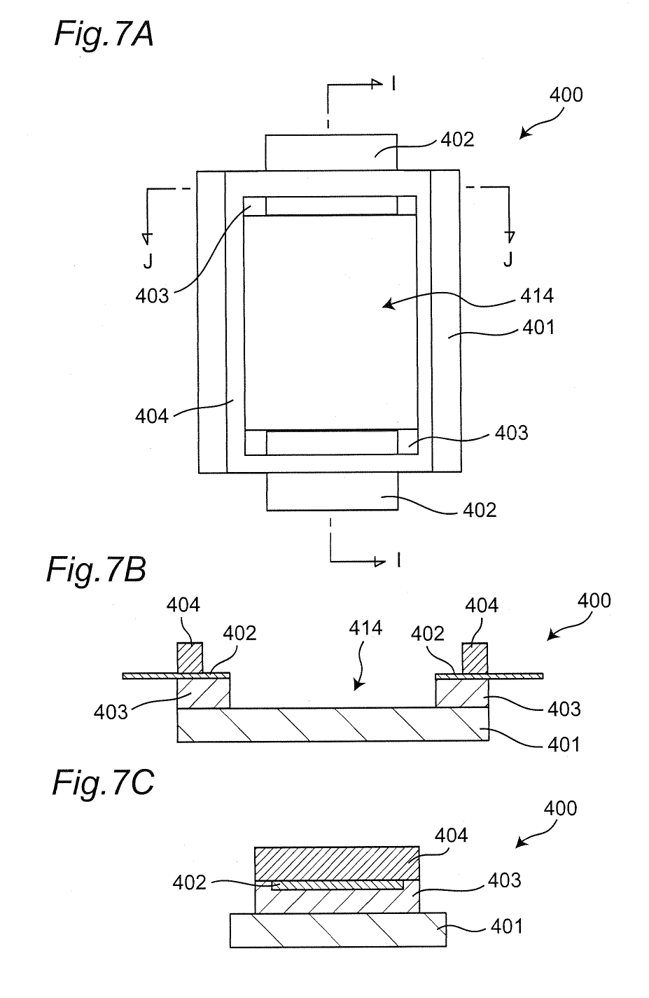

Next, various variations of the semiconductor package 100 according to the embodiment will be described with reference to FIGS. 5A-5C, 6A-6C, and 7A-7C. FIGS. 5A-5C illustrate a semiconductor package 200 according to Variation 1, respectively. FIGS. 6A-6C illustrate a semiconductor package 300 according to Variation 2, respectively. FIGS. 7A-7C illustrate a semiconductor package 400 according to Variation 3, respectively.

(Variation 1)

As shown in FIGS. 5A and 5 C, a heat sink 201 and securing members 203 define a cavity 214. In the semiconductor package 200 according to variation 1, an area in which the heat sink 201 and the securing member 203 have contact with each other is larger than an area in which the securing member 203 and a lead terminal 202 have contact with each other. This can enhance adhesion between the securing member 203 and the heat sink 201, thereby improving the reliability of the semiconductor package 200.

(Variation 2)

As shown in FIG. 6C, a heat sink 301 and securing members 303 define a cavity 314. In the semiconductor package 300 according to variation 2, the securing member 303 has a recessed portion 304 to receive the lead terminal 302. This can enhance adhesion between the securing member 303 and the lead terminal 302, thereby improving the reliability of the semiconductor package 300.

(Variation 3)

As shown in FIGS. 7A-7C, the semiconductor package 400 according to variation 3 has an underlying securing member 403 having a hollow rectangular shape and another securing member 404 having a hollow rectangular shape and formed on lead terminals 402. A heat sink 401 and the securing member 403 define a cavity 414. Placing two kinds of the securing members 403 and 404 to sandwich the lead terminals 402 in this way can increase a contact area between the lead terminal 402 and the securing members 403, 404, thereby enhancing adhesion with each other. Furthermore, a lid to be attached afterwards does not have to be hollow rectangular, which leads to reduced costs.

Any combination of the various embodiments referred to the above can manufacture respective effects.

The semiconductor package and the semiconductor device according to the embodiment of one aspect of the disclosure is useful for a base station for mobile communication handling a high-frequency signal with high-power or a microwave appliance such as a microwave oven.

Although the present invention has been fully described by way of preferred embodiments with reference to the accompanying drawings, it is to be noted here that various changes and variations will be apparent to those skilled in the art. Therefore, unless such changes and variations otherwise depart from the scope of the present invention as set forth in the appended claims, they should be construed as being included therein.

The contents of a specification, drawings and claims of a Japanese patent application No. 2013-69211 filed Mar. 28, 2013 are herein expressly incorporated by reference in their entirety.

1. A semiconductor package comprising:
a heat sink which is a conductive plate and onto which a semiconductor or a matching circuit is to be placed;
a lead terminal which is to be electrically-connected to the semiconductor or the matching circuit on the heat sink; and
a securing member which secures the lead terminal to the heat sink, wherein
the securing member is formed by a composite resin material in which an epoxy resin and a ceramic powder are mixed, and wherein
the securing member is disposed to contact with an oxidized contact surface of the heat sink and an oxidized part has been removed from the heat sink other than the oxidized contact surface.

2. The semiconductor package according to claim 1, wherein the securing member has a thickness larger than that of the semiconductor or the matching circuit on the heat sink, and the heat sink and the securing member define a cavity to accommodate the semiconductor or the matching circuit.

3. The semiconductor package according to claim 1, wherein a glass-transition temperature of the resin mixed in the composite resin material forming the securing member is lower than a heating temperature under which the semiconductor or the matching circuit is bonded onto the heat sink.

4. The semiconductor package according to claim 1, wherein the heat sink or the lead terminal has a roughened part in a position to have contact with the securing member.

5. The semiconductor package according to claim 1, wherein the lead terminal has an oxidized part in a position to have contact with the securing member.

6. The semiconductor package according to claim 5, wherein the heat sink or the lead terminal has a plated portion in a position not to have contact with the securing member.

7. The semiconductor package according to claim 1, wherein an area in which the heat sink and the securing member have contact with each other is larger than an area in which the securing member and the lead terminal have contact with each other.

8. The semiconductor package according to claim 1, wherein the securing member has a recessed portion to receive the lead terminal.

9. The semiconductor package according to claim 1, wherein an opening or a concavo-convex shape is formed in a part of the lead terminal having contact with the securing member.

10. The semiconductor package according to claim 1, wherein the lead terminal is electrically-connected to the heat sink via the securing member, and
the ceramic powder mixed in the composite resin material forming the securing member is high-dielectric.

11. A semiconductor device comprising:
a semiconductor or a matching circuit;
a heat sink which is a conductive plate and onto which the semiconductor or the matching circuit is bonded;
a lead terminal electrically-connected to the semiconductor or the matching circuit on the heat sink; and
a securing member which secures the lead terminal to the heat sink, wherein
the securing member is formed by a composite resin material in which an epoxy resin and a ceramic powder are mixed, and wherein
the securing member is disposed to contact with an oxidized contact surface of the heat sink and an oxidized part has been removed from the heat sink other than the oxidized contact surface.

12. A method for manufacturing a semiconductor device in which a semiconductor package houses a semiconductor or a matching circuit comprising:
making the semiconductor device by disposing a securing member, which is formed by a composite resin material in which an epoxy resin and a ceramic powder are mixed, on an oxidized contact surface of a heat sink which is a conductive plate and by securing a lead terminal to the heat sink;
removing an oxidized part from the heat sink other than the oxidized contact surface;
bonding the semiconductor or the matching circuit onto the heat sink of the semiconductor device by heating; and
electrically-connecting the semiconductor or the matching circuit on the heat sink to the lead terminal, wherein
a shape of the securing member is retained at a heating temperature under which the semiconductor or the matching circuit is bonded onto the heat sink.
